(19) United States
(12) Patent Application Publication
(10) Pub. No.: US 2026/0011975 A1
(43) Pub. Date: Jan. 8, 2026

(54) SEMICONDUCTOR OPTICAL DEVICE AND MANUFACTURING METHOD THEREOF

(71) Applicant: Source Photonics Taiwan, Inc., HSINCHU (TW)

(72) Inventors: HORNG-SHYANG CHEN, HSINCHU COUNTY (TW); HAO-HSIANG TANG, HSINCHU COUNTY (TW); HSUYING CHEN, HSINCHU CITY (TW); THANT ZIN, HSINCHU CITY (TW); NI YEH WU, HSINCHU CITY (TW)

(21) Appl. No.: 18/765,266

(22) Filed: Jul. 7, 2024

(51) Int. Cl. H01S 5/026; H01S 5/042; H01S 5/343

(52) U.S. Cl. CPC H01S 5/0265; H01S 5/04256; H01S 5/343

(57) ABSTRACT

A semiconductor optical device and a method of manufacturing a semiconductor optical device are disclosed. The semiconductor optical device comprises a first active layer and a second active layer on a semiconductor substrate. The first active layer is disposed over a laser section of the semiconductor substrate, and the second active layer is connected to the first active layer and extends over an isolation section, a modulating section and an extraction section of the semiconductor substrate. A cladding layer is disposed over the first active layer and the second active layer, a first electrode is disposed over the first active layer, and a second electrode is disposed over a portion of the second active layer in the modulating section. The first active layer has a first thickness and the second active layer has a second thickness greater than the first thickness. A method of manufacturing the semiconductor optical device is also disclosed.

### TECHNICAL FIELD

The present disclosure relates to a semiconductor optical device and a method of manufacturing the semiconductor optical device, and more particularly to an electro-absorption modulated laser (EML) device and method of manufacturing the EML.

### BACKGROUND

Optical communication systems transmit information between devices by modulating light propagated through an optical fiber or some other optical medium. For example, many existing optical communication systems use a laser to produce a light beam having a narrow line width spectrum that provides a mechanism for modulating the light. The modulation of the light from the laser allows the transmission of the information via the signal.

Optical semiconductor devices in which a semiconductor laser and an external modulator are monolithically integrated with each other are used as medium- to long-distance light sources in optical communication systems.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, dimensions of the various features may be arbitrarily increased or reduced for clarity of discussion.

FIG. 1 is a schematic view of a semiconductor optical device in accordance with some embodiments of the present disclosure.

FIG. 2 is a perspective view of a semiconductor optical device in accordance with some embodiments of the present disclosure.

FIG. 3 is a cross-sectional view of a semiconductor optical device in accordance with some embodiments of the present disclosure.

FIG. 4 is an enlarged partial schematic cross-sectional view of a common electrode, a semiconductor substrate, and a first stacked structure of the semiconductor optical device in FIG. 3.

FIG. 5 is an enlarged partial schematic cross-sectional view of a common electrode, a semiconductor substrate, and a second stacked structure of the semiconductor optical device in FIG. 3.

FIG. 6 is an enlarged partial schematic cross-sectional view of a common electrode, a semiconductor substrate, and a third stacked structure of the semiconductor optical device in FIG. 3.

FIG. 7 is an enlarged partial schematic cross-sectional view of a common electrode, a semiconductor substrate, and a fourth stacked structure of the semiconductor optical device in FIG. 3.

FIG. 8 is a flowchart of a method of manufacturing a semiconductor optical device in accordance with some embodiments of the present disclosure.

FIGS. 9 to 16 are cross-sectional views of intermediate stages of the method of manufacturing the semiconductor optical device, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first,” “second” and “third” describe various elements, components, regions, layers and/or sections, but these elements, components, regions, layers and/or sections should not be limited by these terms. These terms may be only used to distinguish one element, component, region, layer or section from another. The terms such as “first,” “second” and “third” when used herein do not imply a sequence, order, or importance unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the normal deviation found in the respective testing measurements. Also, as used herein, the terms “substantially,” “approximately” or “about” generally mean within a value or range (e.g., within 10%, 5%, 1%, or 0.5% of a given value or range) that can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of time, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

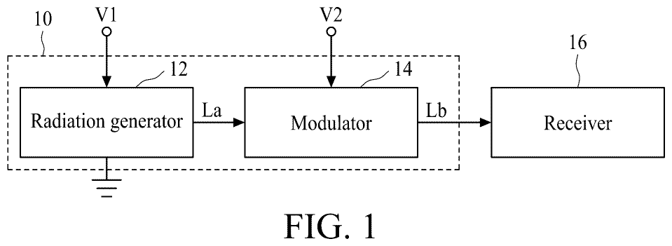

FIG. 1 is a schematic view of a semiconductor optical device 10 and a receiver 16 in accordance with some embodiments of the present disclosure. Referring to FIG. 1, the semiconductor optical device 10 includes a radiation generator 12 and a modulator 14. The radiation generator 12 is, for example, a semiconductor laser. The radiation generator 12 is configured to generate electromagnetic radiation (i.e., light) La having a narrow line width spectrum when a first bias voltage V1 is supplied to the radiation generator 12. In some embodiments, the radiation generator 12 operates in a continuous wave (CW) mode to provide the electromagnetic radiation La having a constant power level.

The modulator 14 is coupled to the radiation generator 12. The modulator 14 is configured to modulate the electromagnetic radiation La from the radiation generator 12 and provide a modulated electromagnetic radiation Lb to the receiver 16. The modulator 14 is, for example, an electro-absorption modulator (EAM). In some embodiments, the modulator 14 is operable to modify an intensity of the electromagnetic radiation La generated by the radiation generator 12. In some embodiments, an absorption efficiency of the modulator 14 changes in response to a second bias voltage V2 applied to the modulator 14. The change of the absorption efficiency is used to selectively either absorb or pass the electromagnetic radiation La. Therefore, changing the second bias voltage V2 of the modulator 14 modulates electromagnetic radiation La.

In some embodiments, the radiation generator 12 and the modulator 14 are integrated on a semiconductor substrate, as discussed below. The radiation generator 12 and the modulator 14 may be fabricated using direct bandgap semiconductors, such as indium phosphide (InP), gallium arsenide (GaAs) and/or related materials that exhibit direct bandgap properties.

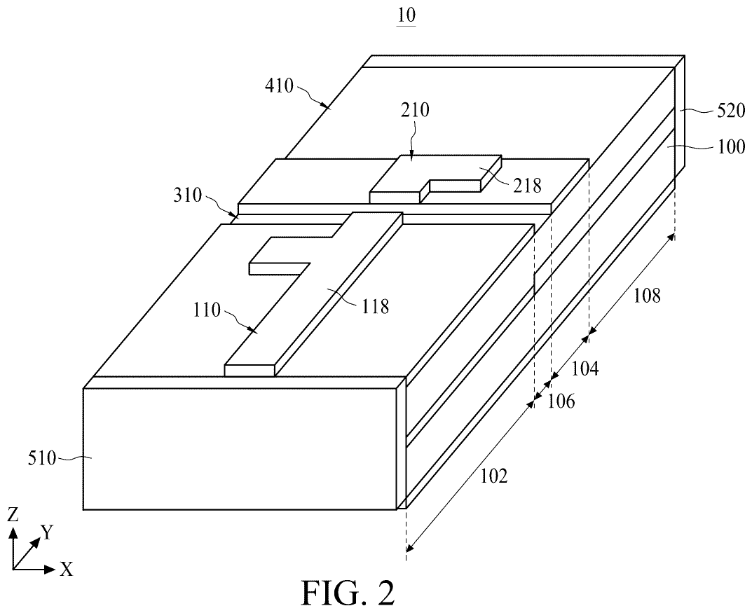

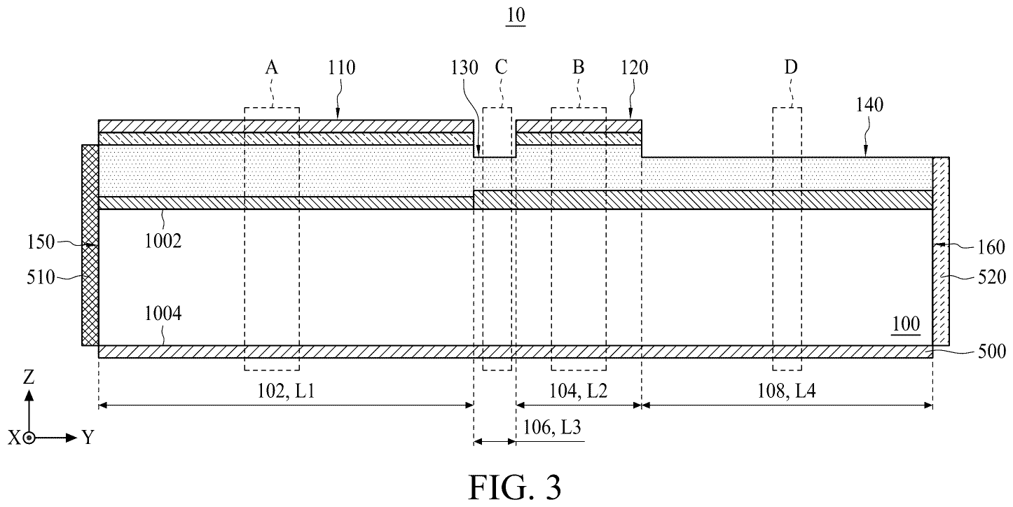

FIG. 2 is a perspective view of the semiconductor optical device 10 in accordance with some embodiments of the present disclosure, and FIG. 3 is a cross-sectional view of the semiconductor optical device 10 in accordance with some embodiments of the present disclosure. Referring to FIGS. 2 and 3, the semiconductor optical device 10 may include a semiconductor substrate 100, a first stacked structure 110, a second stacked structure 210, a third stacked structure 310, a fourth stacked structure 410, a common electrode 500, a high-reflection (HR) coating layer 510, and an anti-reflection (AR) coating layer 520. The semiconductor substrate 100 is, for example, an InP substrate having a first conductivity type. In some embodiments, the first conductivity type is n-type. The semiconductor substrate 100 may also include material such as gallium arsenide (GaAs) or a group III-V compound semiconductor which is perfectly or approximately lattice-matched to InP. The semiconductor substrate 100 has a front surface 1002 and a back surface 1004 opposite to the front surface 1002.

The first stacked structure 110, the second stacked structure 210, the third stacked structure 310, and the fourth stacked structure 410 are respectively disposed on the front surface 1002 of the semiconductor substrate 100. The common electrode 500 is disposed on the back surface 1004 of the semiconductor substrate 100. In some embodiments, the common electrode 500 is grounded. The high-reflection coating layer 510 is disposed on a rear facet 150 of the semiconductor optical device 10. The anti-reflection coating layer 520 is disposed on a front facet 160 of the semiconductor optical device 10. In some embodiments, the rear facet 150 is substantially parallel with the front facet 160. The rear facet 150 and front facet 160 are provided by cutting or sawing process in accordance with an embodiment, or alternatively by etching techniques using etching technologies such as a reactive ion etching process, an inductively-coupled plasma (ICP) etching process, a chemical-assisted ion beam etching process, or another suitable process.

In some embodiments, the first stacked structure 110, which forms the radiation generator 12 (referring to FIG. 1), is arranged in a laser section 102 of the semiconductor substrate 100, and the second stacked structure 210, which forms the modulator 14 (referring to FIG. 1), is arranged in a modulating section 104 of the semiconductor substrate 100. The semiconductor substrate 100 further includes an isolation section 106 and an extraction section 108, which are arranged on either side of the modulating section 104. In some embodiments, the isolation section 106 is between the laser section 102 and the modulating section 104. The third stacked structure 310 is arranged in the isolation section 106 and connects the first stacked structure 110 to the second stacked structure 210. The third stacked structure 310 is used to transmit the electromagnetic radiation La (referring to FIG. 1) generated by the radiation generator 12 to the modulator 14. The fourth stacked structure 410 is arranged in the extraction section 108 of the semiconductor optical device 10. The fourth stacked structure 410 is connected to the second stacked structure 210. The electromagnetic radiation passing through the modulator 14 (i.e., modulated electromagnetic radiation) may exit the semiconductor optical device 10 through the extraction section 108 and the anti-reflection coating layer 520. In some embodiments, the fourth stacked structure 410 may be utilized to improve uniformity of the modulated electromagnetic radiation Lb (referring to FIG. 1). In some embodiments, the fourth stacked structure 410 is provided to improve optical output power of the semiconductor optical device 10. The fourth stacked structure 410 may improve a high frequency characteristic of the semiconductor optical device 10.

In some embodiments, the laser section 102 has a first length L1, and the modulating section 104 has a second length L2 less than the first length L1. In some embodiments, the second length L2 is less than a half of the first length L1. For example, the first length L1 is about 450 μm, and the second length L2 is about 150 μm. The isolation section 106 may have a third length L3 less than the second length L2. The third length L3 is, for example, about 50 μm. The extraction section 108 may have a fourth length L4 between the first length L1 and the second length L2. The fourth length L4 is, for example, about 350 μm.

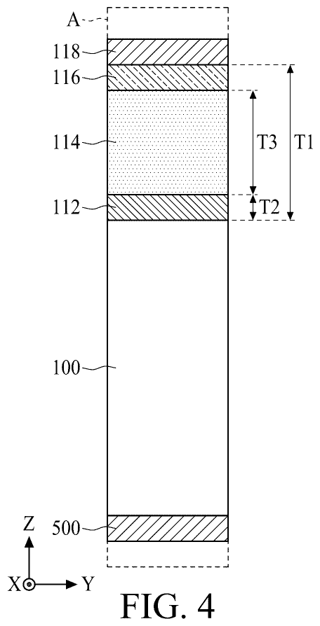

The first stacked structure 110 is utilized to generate visible or invisible light through stimulated emission. FIG. 4 is an enlarged partial schematic cross-sectional view of the common electrode 500, the semiconductor substrate 100, and the first stacked structure 110 of FIG. 3. Referring to FIG. 4, the first stacked structure 110 may include a first active layer 112, a first cladding layer 114, a first capping layer 116, and a first electrode 118 sequentially disposed on the semiconductor substrate 100. The first stacked structure 110 has a first thickness T1. With reference to FIGS. 1 to 4, the first bias voltage V1 is applied to the first stacked structure 110 via the first electrode 118. The first electrode 118 may have a T-shaped profile as shown in FIG. 2 or some other suitable profile.

The first active layer 112 is capable of generating electromagnetic radiation of predetermined wavelength and gain for lasing. The first active layer 112 is, for example, where the stimulated emission occurs. In some embodiments, the first active layer 112 includes alternating films of low band-gap energy material and high band-gap energy material. The first active layer 112 may include a multiple quantum well (MQW) structure. For example, the MQW structure in the first active layer 112 includes one or more phosphorus-containing films such as indium gallium arsenide phosphide (InGaAsP) or one or more Al-containing films such as indium gallium aluminum arsenic (InGaAlAs). Alternative materials for forming the first active layer 112 may include InGaAs and AlGaNAs. The MQW structure may include a series of between 4 and 20 wells and potential barriers. In some embodiments, the first active layer 112 has a first effective refractive index of about 3.19. The first effective refractive index may refer to an average refractive index applied to light propagating through the first active layer 112 in the z-direction.

In some embodiments, carrier injection into the first active layer 112 is performed by applying a forward bias across the first electrode 118 and the common electrode 500, thereby causing a recombination of carriers (holes and electrons) in the first active layer 112. The MQW structure transduces carriers into photons. As a result, electromagnetic radiation having the predetermined wavelength corresponding to a band-gap energy of the first active layer 112 is produced. In some embodiments, the first active layer 112 has a second thickness T2 of about 200 μm.

The first cladding layer 114 is formed of a III-V group compound semiconductor. The first cladding layer 114 may have a second conductivity type different from the first conductivity type. For example, the first cladding layer 114 is a p-type InP layer. The first cladding layer 114 and the semiconductor substrate 100 confine the holes and electrons in the first active layer 112. In some embodiments, the semiconductor substrate 100 has a first impurity concentration, and the first cladding layer 114 has a second impurity concentration substantially same as the first impurity concentration. In some embodiments, the first cladding layer 114 has a thickness T3 greater than the second thickness T2.

The first capping layer 116 is a layer of a heavily doped semiconductor of the second conductivity type. In some embodiments, the first capping layer 116 has a third impurity concentration greater than the first or second impurity concentration. The third impurity concentration allows the first capping layer 116 having a low contact resistance with the first electrode 118. The first capping layer 116 may function as an ohmic contact layer of the semiconductor optical device 10. The first capping layer 116 also provides a path to allow heat to escape from the first active layer 112. In some embodiments, the first capping layer 116 includes indium gallium arsenide (InGaAs). The first capping layer 116 may be formed by any suitable deposition and doping methods.

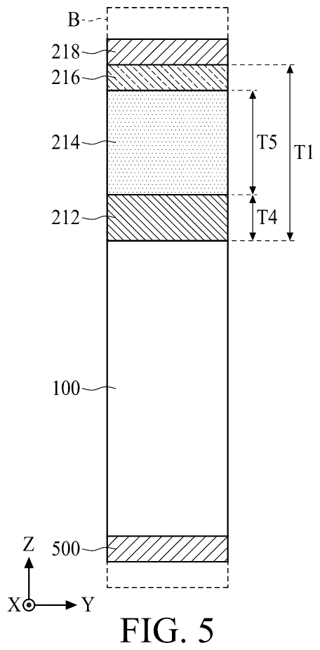

FIG. 5 is an enlarged partial schematic cross-sectional view of the common electrode 500, the semiconductor substrate 100, and the second stacked structure 210 of FIG. 3. Referring to FIG. 5, the second stacked structure 210 includes a second active layer 212, a second cladding layer 214, a second capping layer 216, and a second electrode 218 sequentially disposed on the semiconductor substrate 100. With reference to FIGS. 3 and 5, the second bias voltage V2 is applied to the second stacked structure 120 via the second electrode 218. The second electrode 218 may have an L-shaped profile as shown in FIG. 2 or some other suitable profile.

The second active layer 212 is in contact with the semiconductor substrate 100. The second active layer 212 may include a plurality of semiconductor films to form a MQW structure. In some embodiments, the first active layer 112 is used to generate the electromagnetic radiation, and the second active layer 212 is used to absorb the electromagnetic radiation from the first active layer 112 based on the second bias voltage V2. Thus, a number of the quantum wells in the second active layer 212 is greater than a number of the quantum wells required for the first active layer 112. Therefore, the second active layer 212 have a layer structure different from that of the first active layer 112. In some embodiments, the second active layer 212 has a second effective refractive index greater than the first effective refractive index. For example, the second effective refractive index is about 3.29.

With reference to FIGS. 4 and 5, the second active layer 212 has a fourth thickness T4 greater than the second thickness T2 of the first active layer 112. In some embodiments, the second active layer 212 may have the fourth thickness T4 that is at least 1.2 times the second thickness T2 of the first active layer 112. The fourth thickness T4 is, for example, about 250 μm.

The second cladding layer 214 has a material composition same as that of the first cladding layer 114. The second cladding layer 214 may have a fifth thickness T5 less than the third thickness T3 of the first cladding layer 114. In some embodiments, a sum of the second thickness T2 and the third thickness T3 is substantially equal to a sum of the fourth thickness T4 and the fifth thickness T5.

The second capping layer 216 has a material composition same as that of the first capping layer 116, and the second electrode 218 has a material composition same as that of the first electrode 118. In addition, the first and second capping layers 116 and 216 may have substantially the same thickness, and the first and second electrodes 118 and 218 may have substantially the same thickness.

A principle of operation of an EAM is based on application of an electric field to cause a change in an absorption spectrum of light passing through the EAM, allowing the light to undergo amplitude modulation. A typical EAM has a waveguide and electrodes for applying an electric field in a direction perpendicular to a direction of propagation of the light. In order to achieve a high extinction ratio, EAMs typically include a quantum well structure that provides a sharp absorption spectrum that is very sensitive to the applied voltage.

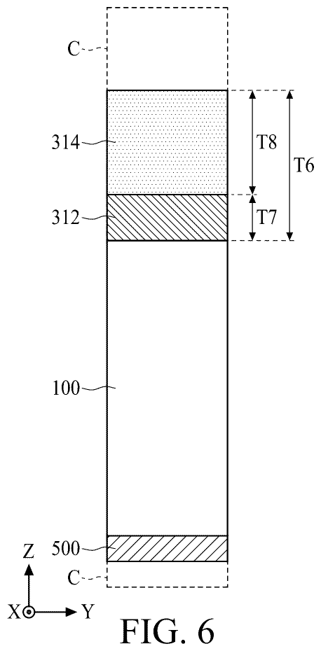

FIG. 6 is an enlarged partial schematic cross-sectional view of the common electrode 500, the semiconductor substrate 100, and the third stacked structure 310 of FIG. 3. Referring to FIGS. 3 and 6, the third stacked structure 310 includes a third active layer 312 and a third cladding layer 314 sequentially disposed on the semiconductor substrate 100. In some embodiments, an interface between the semiconductor substrate 100 and the first active layer 112 is substantially coplanar with an interface between the semiconductor substrate 100 and the third active layer 312. In addition, an interface between the semiconductor substrate 100 and the second active layer 212 is substantially coplanar with the interface between the semiconductor substrate 100 and the third active layer 312.

The third active layer 312 is used to guide the electromagnetic radiation from the first active layer 112 to the second active layer 212. Since there is an interface between two active layers having different refractive indexes, scattering of the electromagnetic radiation occurs at the interface. The electromagnetic radiation scattered by the interface and entering the second active layer 212 will be absorbed by the second active layer 212. Thus, the absorption of electromagnetic radiation guided by the second active layer 212 is reduced when a great amount of scattered electromagnetic radiation enters the second active layer 212 (such as the interface is close to an edge of the second active layer 212), resulting in the modulated electromagnetic radiation Lb (referring to FIG. 1) being different from the requirement. The second and third active layers 212 and 312 having same layer structure reduce the refractive index difference. The third cladding layer 314 has a material composition same as that of the first cladding layer 114. The third stacked structure 310 has a sixth thickness T6 less than the first thickness T1 of the first stacked structure 110 or the second stacked structure 210. In some embodiments, the third active layer 312 has a seventh thickness T7 that is substantially equal to the fourth thickness T4, and the third cladding layer 314 has an eighth thickness T8 that is substantially equal to the fifth thickness T5.

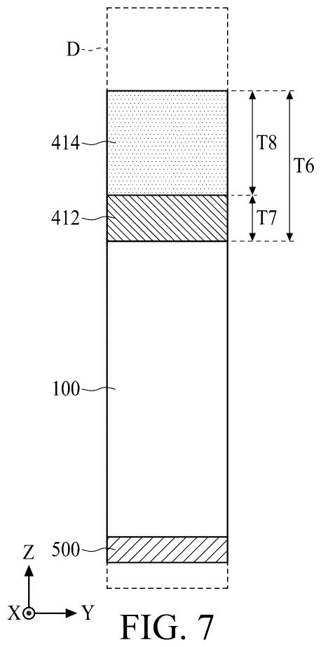

FIG. 7 is an enlarged partial schematic cross-sectional view of the common electrode 500, the semiconductor substrate 100, and the fourth stacked structure 410 of FIG. 3. Referring to FIG. 7, the fourth stacked structure 410 includes a fourth active layer 412 and a fourth cladding layer 414 sequentially disposed on the semiconductor substrate 100. In some embodiments, an interface between the semiconductor substrate 100 and the fourth active layer 412 is substantially coplanar with the interface between the semiconductor substrate 100 and the second active layer 212. The second active layer 212, the third active layer 312, and the fourth active layer 412 may have a same layer structure to reduce the refractive index difference. In some embodiments, the second active layer 212, the third active layer 312, and the fourth active layer 412 are integrally formed.

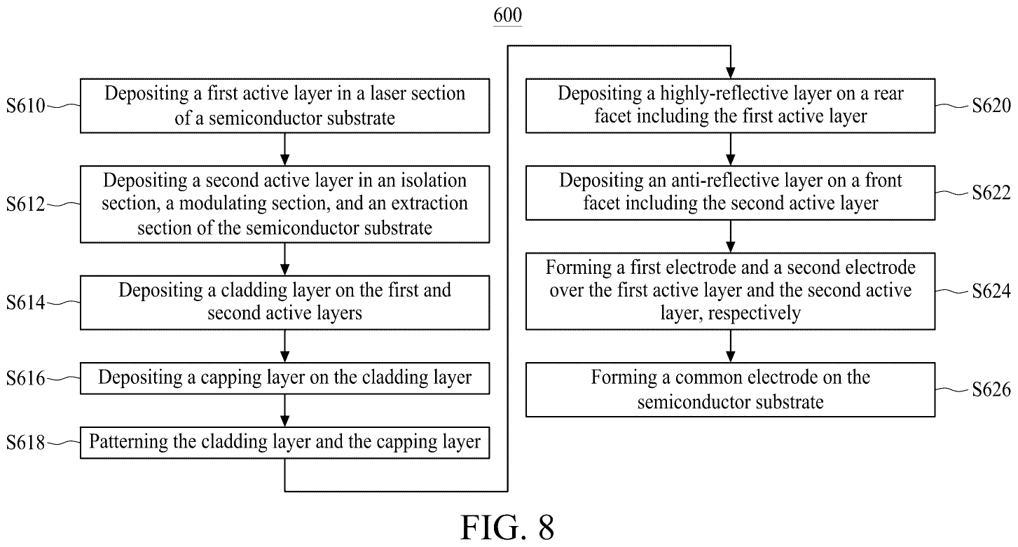

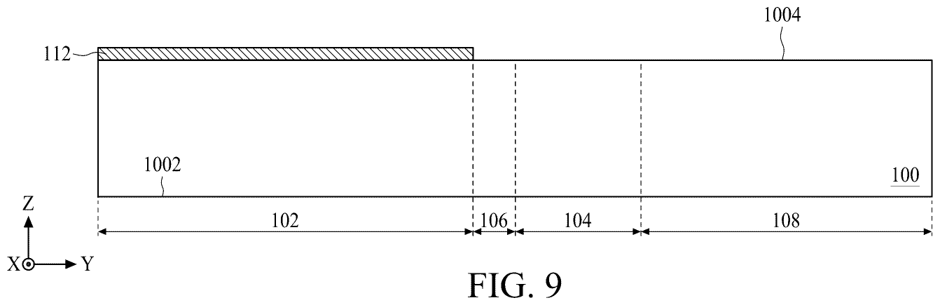

FIG. 8 is a flowchart of a method 600 of manufacturing a semiconductor optical device in accordance with some embodiments of the present disclosure. FIGS. 9 to 15 are cross-sectional views of intermediate stages of the method 600 of manufacturing the semiconductor optical device 10, in accordance with some embodiments of the present disclosure. In the following discussion, the manufacturing stages shown in FIGS. 9 to 15 are discussed in reference to the process steps shown in FIG. 8. It should be understood that additional steps can be provided before, during, and after the steps shown in FIG. 8, and some of the steps described below can be replaced or eliminated, for additional embodiments of the method 600. The order of the steps may be changed.

Referring to FIG. 9, a first active layer 112 is deposited on a laser section 102 of a semiconductor substrate 100 in accordance with step S610 in FIG. 8. The semiconductor substrate 100 has a front surface 1002 and a back surface 1004 opposite to the front surface 1002. In some embodiments, the semiconductor substrate 100 is made of an InP-based group III-V compound semiconductor. The InP-based group III-V compound semiconductor includes InP and a group III-V compound semiconductor which is perfectly or approximately lattice-matched to InP. The InP-based group III-V compound semiconductor further includes a group III-V compound semiconductor which is pseudomorphic to InP. The term “pseudomorphic” usually refers to a semiconductor layer that has a crystal structure in which a lattice constant in a laminate in-plane direction is equal to a lattice constant in a laminate in-plane direction of InP, and in which the lattice constant in a laminating direction is different from the lattice constant in a laminating direction of InP. However, in some embodiments, “pseudomorphic” includes not only an ideal state in which a lattice mismatch is not present but also a state in which a minor lattice defect (which is described below) not adversely affecting device characteristics is present. Examples of the group III-V compound semiconductor which is pseudomorphic to InP and is used in the semiconductor substrate 100 include InGaAs, InGaAlAs, InGaAsP, InGaAlAsP, and the like.

The first active layer 112 may include a first stacked film structure that forms a first multiple quantum well (MQW) structure. In some embodiments, the first stacked film structure is epitaxially grown using a metal-organic chemical vapor deposition (MOCVD) process, although other processes, such as a molecular beam epitaxy (MBE) process, a hydride vapor phase epitaxy (HYPE) process, a liquid phase epitaxy (LPE) process, or the like, may alternatively be utilized.

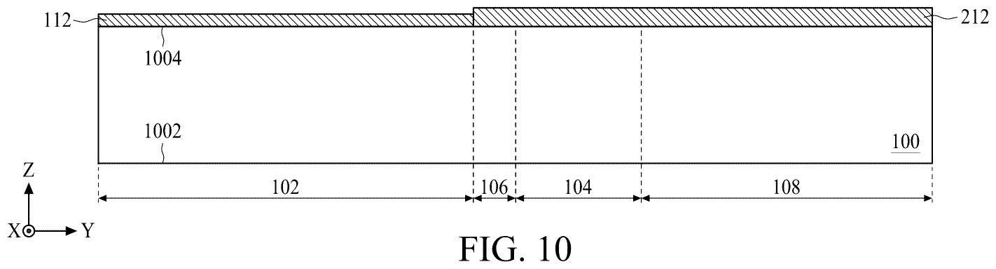

Referring to FIG. 10, a second active layer 212 is deposited on an isolation section 106, a modulation section 104, and an extraction section 108 of the semiconductor substrate 100 in accordance with step S612 in FIG. 8. The second active layer 212 includes a second stacked film structure that forms a second multiple quantum well (MQW) structure. The second stacked film structure is epitaxially grown using a MOCVD process, an MBE process, a HYPE process, an LPE process, or the like.

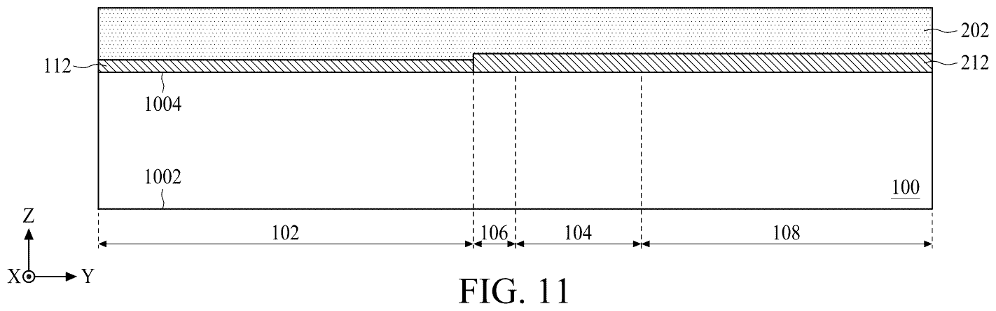

Referring to FIG. 11, a cladding layer 202 is deposited on the first active layer 112 and the second active layer 212 in accordance with step S614 in FIG. 8. The cladding layer 202 fully covers the first active layer 112 and the second active layer 212. The cladding layer 202 may be deposited using a MOCVD process. In some embodiments, the cladding layer 202 may be planarized, such as by a chemical mechanical polishing (CMP) process, to have a substantially planar top surface.

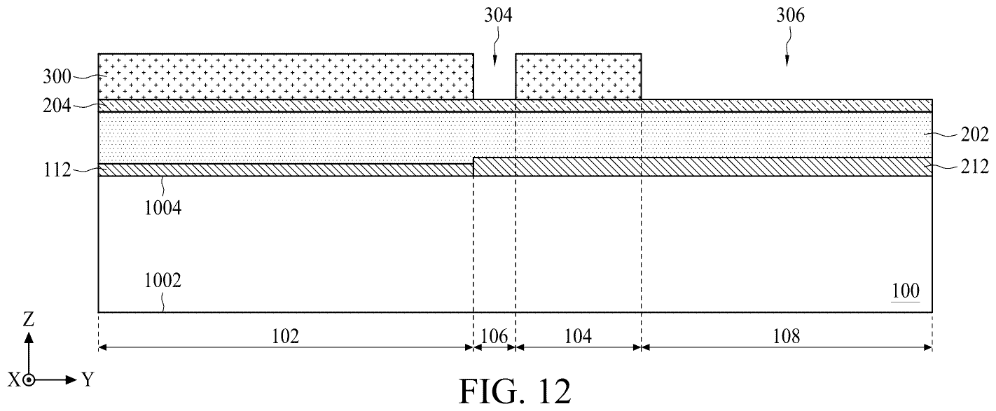

Referring to FIG. 12, a capping layer 204 is deposited on the cladding layer 202 in accordance with step S616 in FIG. 8. The capping layer 204 may be deposited with a substantially uniform thickness using an acceptable deposition operation such as a spin-coating operation, a MOCVD operation, or the like. In some embodiments, after the deposition of the capping layer 204, an implantation process may be performed to implant dopant ions into the capping layer 204. The capping layer 204 is heavily doped so as to minimize a resistance of the capping layer 204.

In some embodiments, after the formation of the capping layer 204, a patterned mask layer 300 is formed on the capping layer 204. The patterned mask layer 300 includes a first window 302 and a second window 304 to expose portions of the capping layer 204 in the isolation section 106 and the extraction section 108.

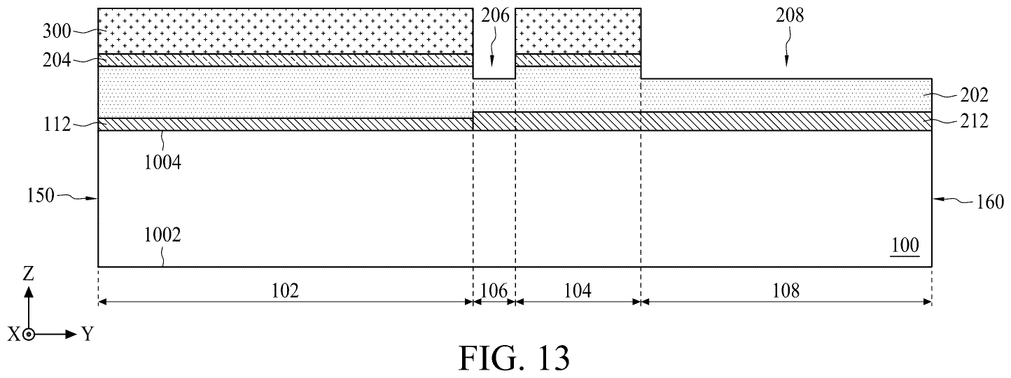

Referring to FIG. 13, the cladding layer 202 and the capping layer 204 are patterned in accordance with step S618 in FIG. 8. Hence, a first trench 206 and a second trench 208 that penetrate through the capping layer 204 and extend into the cladding layer 202 are formed in the isolation section 106 and the extraction section 108, respectively. After the patterned mask layer 300 is formed, an etching operation is performed to etch the capping layer 204 and the cladding layer 202, thereby forming the first trench 206 and the second trench 208. In some embodiments, the capping layer 204 and the cladding layer 202 are anisotropically etched by a plasma-based etching process, such as a reactive ion etching (RIE) process, or the like. The patterned mask layer 300 is used to limit a high-energy plasma etch to a desired pattern for the first trench 206 and the second trench 208. After the first trench 206 and the second trench 208 are formed, the patterned mask layer 300 is removed using an ashing and/or a wet strip process, for example.

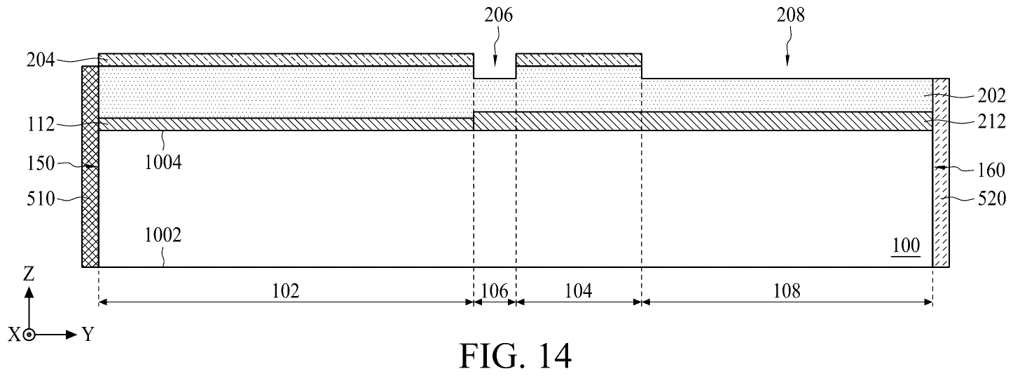

Referring to FIG. 14, a highly-reflective layer 510 is disposed at a rear facet 150 of the semiconductor optical device 10 in accordance with step S620 in FIG. 8. The highly-reflective layer 510 can be used to help confine light by using thin cladding regions without causing unacceptable levels of loss. The highly-reflective layer 510 may include a single layer or multilayer structure. In some embodiments, the highly-reflective layer 510 is free from metal. In some embodiments, the highly-reflective layer 510 of single layer may include a dielectric material having a refractive index greater than 2, such as tantalum pentoxide (Ta₂O₅). The highly-reflective layer 510 may be formed on the rear facet 150 of the semiconductor optical device 10 using an e-beam technique, a sputter technique, or an evaporation technique. In some embodiments, the highly-reflective layer 510 of the multilayer structure has odd number of dielectric films. For example, the highly-reflective layer 510 includes alternating first dielectric film and second dielectric film having indices greater than 1.4. One of the first dielectric films is in contact with the rear facet 150. The first dielectric film may have a first refractive index of about 2. The first dielectric films may include tantalum pentoxide (Ta₂O₅). Each second dielectric film is sandwiched between two first dielectric films and has a second refractive index of 1.5. The second dielectric film(s) may include silicon dioxide (SiO₂).

Subsequently, an anti-reflective layer 520 is disposed at a front facet 160 of the semiconductor optical device 10 in accordance with step S622 in FIG. 8. The anti-reflective layer 520 is used to reduce reflection of the electromagnetic radiation emitted by the front facet 160 of the semiconductor optical device 10. A suitable anti-reflective layer 520 includes, but is not limited to, single-layer coatings such as silicon nitride or aluminum oxide, or multi-layer coatings, which may contain silicon nitride, aluminum oxide, and/or silica.

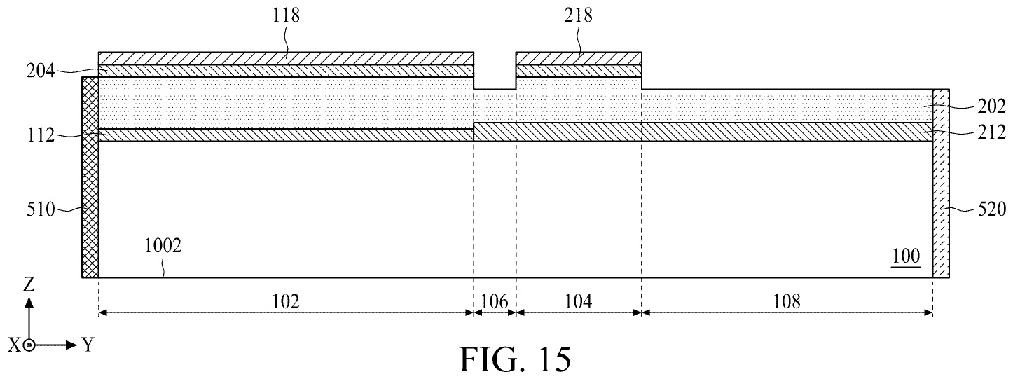

Referring to FIG. 15, a first electrode 118 and a second electrode 218 are deposited on remaining portions of the capping layer 204 in accordance with step S624 in FIG. 8. In some embodiments, the first electrode 118 is arranged in the laser section 102, and the second electrode 218 is arranged in the modulating section 104. In some embodiments, the first and second electrodes 118 and 218 are formed by applying a first electrode material on remaining portions of the capping layer 204 by a deposition process. Examples of the first electrode material include, but are not limited to, titanium (Ti), platinum (Pt), gold (Au), and the like.

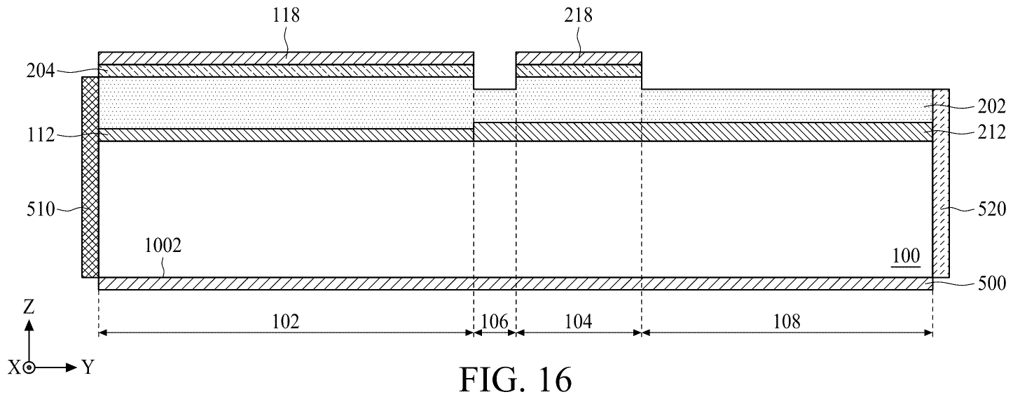

Referring to FIG. 16, a common electrode 500 is deposited at the back surface 1004 of the semiconductor substrate 100 in accordance with step S626 in FIG. 8. Consequently, the semiconductor optical device 10 is completely formed. The common electrode 500 may be formed by applying a second electrode material on the semiconductor substrate 100 by, for example, deposition or sputtering. The second electrode material may be same as or different from the first electrode material. The common electrode 500 may have a single-layered structure or a multi-layered structure including at least two layers.

In accordance with some embodiments of the present disclosure, a semiconductor optical device is provided. The semiconductor optical device includes a semiconductor substrate, a first active layer, a second active layer, a first electrode, and a second electrode. The first active layer is disposed on the semiconductor substrate, wherein the first active layer has a first thickness. The second active layer is disposed on the semiconductor substrate and includes a first end coupled to the first active layer and a second end distal to the first active layer, wherein the second active layer has a second thickness greater than the first thickness. The first metal pad is disposed over the first active layer. The second metal pad is disposed over the second active layer and spaced apart from the first edge and second edges of the second active layer.

In accordance with some embodiments of the present disclosure, a semiconductor optical device comprises a radiation generator, a modulator, and an extractor. The radiation generator includes a first active layer for generating electromagnetic radiation, wherein the first active layer has a first thickness. The modulator is coupled to the radiation generator and includes a second active layer having a second thickness, wherein the second thickness is greater than the first thickness. The extractor includes a third active layer connected to the second active layer, wherein the third active layer has the second thickness.

In accordance with some embodiments of the present disclosure, a method of manufacturing a semiconductor optical device is provided. The method includes steps of depositing a first active layer and a second active layer on a semiconductor substrate, wherein the first active layer is arranged in a laser section of the semiconductor substrate, and the second active layer is connected to the first active layer and extends across an isolation section, a modulating section and an extraction section of the semiconductor substrate; depositing a cladding layer on the first active layer and the second active layer; removing portions of the cladding layer to form a first trench in the isolation section and a second trench in the extraction section; depositing a first electrode over the first active layer; and depositing a second electrode over a portion of the second active layer in the modulating section, wherein the first active layer has a first thickness and the second active layer has a second thickness greater than the first thickness.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor optical device, comprising:
a semiconductor substrate;
a first active layer disposed on the semiconductor substrate, wherein the first active layer has a first thickness;
a second active layer disposed on the semiconductor substrate and comprising a first end coupled to the first active layer and a second end distal to the first active layer, wherein the second active layer has a second thickness greater than the first thickness;
a first electrode disposed over the first active layer; and
a second electrode disposed over the second active layer and spaced apart from the first electrode.

2. The semiconductor optical device of claim 1, wherein the first active layer has a first length, and the second active layer has a second length greater than the first length.

3. The semiconductor optical device of claim 2, wherein:
the semiconductor substrate is defined with a laser section, a modulating section, an isolation section, and an extraction section,
the isolation section and the extraction section are disposed on either side of the modulating section,
the isolation section is between the laser section and the modulating section,
the first active layer is arranged in the laser section, and
the second active layer is arranged in the modulating section, the isolation section, and the extraction section.

4. The semiconductor optical device of claim 3, wherein the laser section has a first length, the modulating section has a second length less than the first length, the isolation section has a third length less than the second length, and the extraction section has a fourth length less than the first length and greater than the second length.

5. The semiconductor optical device of claim 3, wherein the fourth length is about 350 μm.

6. The semiconductor optical device of claim 3, further comprising:
a first cladding layer arranged in the laser section and the modulating section, wherein the first cladding layer is disposed between the first active layer and the first electrode and between the second active layer and the second electrode, and the first cladding layer has a third thickness; and
a second cladding layer arranged in the isolation section and the extraction section and on the second active layer, wherein the second cladding layer has a fourth thickness less than the third thickness.

7. The semiconductor optical device of claim 6, further comprising a capping layer between the first cladding layer and the first electrode and between the first cladding layer and the second electrode.

8. The semiconductor optical device of claim 1, wherein an interface between the semiconductor substrate and the first active layer is substantially coplanar with an interface between the semiconductor substrate and the second active layer.

9. The semiconductor optical device of claim 1, wherein the first and second active layers comprise multi-quantum-well (MQW) structures.

10. The semiconductor optical device of claim 1, wherein the first active layer has a first effective refractive index, and the second active layer has a second effective refractive index greater than the first effective refractive index.

11. A semiconductor optical device, comprising:
a radiation generator comprising a first active layer for generating electromagnetic radiation, wherein the first active layer has a first thickness;
a modulator coupled to the radiation generator and comprising a second active layer having a second thickness, wherein the second thickness is greater than the first thickness; and
an extractor comprising a third active layer connected to the second active layer, wherein the third active layer has the second thickness.

12. The semiconductor optical device of claim 11, wherein the first active layer has a first length, the second active layer has a second length less than the first length, and the third active layer has a third length less than the first length and greater than the second length.

13. The semiconductor optical device of claim 12, wherein the third length is greater than twice of the second length.

14. The semiconductor optical device of claim 11, further comprising an isolator comprising a fourth active layer connecting the first active layer to the second active layer, wherein the fourth active layer has the second thickness.

15. The semiconductor optical device of claim 14, wherein the second active layer, the third active layer and the fourth active layer are integrally formed.

16. The semiconductor optical device of claim 14, further comprising:
a substrate under the first active layer, the second active layer, the third active layer and the fourth active layer;
a first cladding layer disposed on the first active layer and the second active layer, wherein the first cladding layer has a third thickness; and
a second cladding layer disposed on the third active layer and the fourth active layer, wherein the second cladding layer has a fourth thickness less than the third thickness.

17. The semiconductor optical device of claim 11, further comprising:
a highly-reflective layer disposed at a rear facet of the semiconductor optical device; and
an anti-reflective layer disposed at a front facet of the semiconductor optical device.

18. A method of manufacturing a semiconductor optical device, comprising:
depositing a first active layer and a second active layer on a semiconductor substrate, wherein the first active layer is arranged in a laser section of the semiconductor substrate, and the second active layer is connected to the first active layer and extends across an isolation section, a modulating section and an extraction section of the semiconductor substrate;
depositing a cladding layer on the first active layer and the second active layer;
removing portions of the cladding layer to form a first trench in the isolation section and a second trench in the extraction section;
depositing a first electrode over the first active layer; and
depositing a second electrode over a portion of the second active layer in the modulating section,
wherein the first active layer has a first thickness, and the second active layer has a second thickness greater than the first thickness.

19. The method of claim 18, further comprising depositing a capping layer on the cladding layer prior to the formation of the first trench and the second trench, wherein the first trench and the second trench penetrate the capping layer.

20. The method of claim 18, further comprising depositing a common electrode on a back surface of the semiconductor substrate.
